(19) United States
(12) Patent Application Publication
(10) Pub. No.: US 2017/0154963 A1
(43) Pub. Date: Jun. 1, 2017

(54) CONTROLLED DOPING FROM LOW TO HIGH LEVELS IN WIDE BANDGAP SEMICONDUCTORS

(71) Applicant: North Carolina State University, Raleigh, NC (US)

(72) Inventors: Ramon R. Collazo, Raleigh, NC (US); Zlatko Sitar, Apex, NC (US); James Tweedie, Raleigh, NC (US)

(21) Appl. No.: 15/349,323

(22) Filed: Nov. 11, 2016

Related U.S. Application Data
(60) Provisional application No. 62/261,110, filed on Nov. 30, 2015.

(51) Int. Cl. H01L 29/20; H01L 33/32; H01L 21/263; H01L 33/00; H01L 21/268; H01L 21/67; H01L 29/36; H01S 5/30

(52) U.S. Cl. CPC H01L 29/2003; H01L 29/36; H01L 33/32; H01S 5/3013; H01L 33/0075; H01L 21/2686; H01L 21/67115; H01L 21/263

(57) ABSTRACT

The energy of formation of a point defect in a compound semiconductor is a function of the process conditions and the Fermi energy (the energy of the charge carriers). In wide bandgap semiconductors or insulators, the contribution of this energy to the formation energy of charged point defects is significant. For doping for n- or p-type conductivity, the larger the energy gap, the higher the concentration of compensating point defects that is at equilibrium with the system. This is a fundamental problem with wide bandgap materials that will be directly addressed with these capabilities. In this approach, minority carrier injection is used to modify the quasi-Fermi level to control the formation energy of the point defects. Increasing the formation energy of unwanted point defect through an external excitation that leads to excess minority carriers during the growth of the semiconductor device structure leads to a reduction in compensating point defects.

### CROSS-REFERENCE TO RELATED APPLICATION(S)

The present application claims priority to U.S. Provisional Patent Application No. 62/261,110, entitled: Controlled Doping from Low to High Levels in Wide Bandgap Semiconductors, filed on Nov. 30, 2015, the content of which is incorporated herein by reference.

### BACKGROUND

Charged point defects in compound semiconductors strongly determine electronic and optical properties. The energy of formation of a point defect is a function of the process conditions and the Fermi energy. In wide bandgap semiconductors or insulators, the contribution of the Fermi energy to the formation energy of charged point defects is significant. For the practical case of doping for n- or p-type conductivity, the larger the energy gap, the higher the concentration of compensating point defects that is at equilibrium with the system. This is a fundamental problem with wide bandgap materials.

Therefore, it may be desirable to have a method and apparatus that takes into account at least some of the issues discussed above, as well as possibly other issues.

### BRIEF SUMMARY

Example implementations of the present disclosure address the problem of higher concentrations of compensating point defects in semiconductors or insulators, and in particular, wide bandgap semiconductors or insulators. It has been traditionally understood that the Fermi level is not a free parameter easily modified during an experiment and is only controlled by doping. Increasing the formation energy of unwanted point defects through an external excitation leads to a reduction in compensating point defects and, thus, endows the ability to directly control the Fermi level during a growth experiment to influence the formation of point defects.

Semiconductor or insulator structures according to example implementations of the present disclosure may have carrier concentrations greater or less than that of corresponding conventional semiconductor or insulator structures. The carrier concentrations of these structures may be controllable over a wider range than may be otherwise achieved. Although applicable to any of a number of different semiconductors, at least some example implementations may lead to AlₓGa₍₁₋ₓ₎N alloys from (0≦x≦1) or oxides with controllable carrier concentrations between 1×10¹⁴ cm⁻³ and 5×10²⁰ cm⁻³, as compared to corresponding conventional semiconductor alloys or oxides that may only achieve carrier concentrations between 1×10¹⁷ cm³ and 2×10¹⁹ cm³. Example implementations may also lead to measurable Hall mobility that reach the expected theoretical limit for alloy scattering or their single end members.

Many applications such as optoelectronics and power electronics rely on the functionality of wide bandgap materials. But to reach their full potential, it is necessary to realize point defect control in order to enhance the doping capabilities. Examples of the possibilities of the proposed enabling technology are increasing the efficiency and operational range of ultraviolet (UV) light emitting diodes (LEDs), deep ultraviolet (DUV) laser diodes, power rectifiers, as well as switches. This research will directly lead to materials that will be used for applications that deal with the preservation and extension of natural resources by allowing for: (1) the efficient use and transmission of electrical energy, (2) the availability of clean potable water through disinfection by the use of UV LEDs, and (3) the detection of pollutants and other effluents.

The present disclosure thus includes, without limitation, the following example implementations. Some example implementations provide a structure comprising a doped crystalline layer composed of a semiconductor or an insulator into which an n- or p-dopant has been introduced, and into which a concentration of excess minority carriers has been introduced during processing of the doped crystalline layer, wherein the doped crystalline layer with the concentration of excess minority carriers has a carrier concentration greater or less than the carrier concentration of a corresponding doped crystalline layer without the concentration of excess minority carriers introduced during processing of the corresponding doped crystalline layer.

In some example implementations of the structure of any preceding or any subsequent example implementation, or any combination thereof, the doped crystalline layer is composed of a semiconductor into which the n- or p-dopant has been introduced, and into which the concentration of excess minority carriers has been introduced during processing of the doped crystalline layer.

In some example implementations of the structure of any preceding or any subsequent example implementation, or any combination thereof, the doped crystalline layer is a doped AlₓGa₍₁₋ₓ₎N layer from (0≦x≦1), and the doped crystalline layer with the concentration of excess minority carriers has a carrier concentration between 1×10¹⁴ cm⁻³ and 5×10²⁰ cm⁻³.

In some example implementations of the structure of any preceding or any subsequent example implementation, or any combination thereof, the doped crystalline layer is composed of an insulator into which the n- or p-dopant has been introduced, and into which the concentration of excess minority carriers has been introduced during processing of the doped crystalline layer.

In some example implementations of the structure of any preceding or any subsequent example implementation, or any combination thereof, the doped crystalline layer is an oxide, and the doped crystalline layer with the concentration of excess minority carriers has a carrier concentration between 1×10¹⁴ cm⁻³ and 5×10²⁰ cm⁻³.

In some example implementations of the structure of any preceding or any subsequent example implementation, or any combination thereof, the concentration of excess minority carriers has been introduced during growth of the doped crystalline layer. In some example implementations of the structure of any preceding or any subsequent example implementation, or any combination thereof, the concentration of excess minority carriers has been introduced during post-growth processing of the doped crystalline layer.

In some example implementations of the structure of any preceding or any subsequent example implementation, or any combination thereof, the structure is for production of a ultraviolet (UV) light emitting diode.

In some example implementations of the structure of any preceding or any subsequent example implementation, or any combination thereof, the structure is for production of a deep ultraviolet (DUV) laser diode.

In some example implementations of the structure of any preceding or any subsequent example implementation, or any combination thereof, the structure is for production of a power rectifier or a switch.

Some example implementations provide a structure prepared by a process comprising processing a doped crystalline layer composed of a semiconductor or an insulator into which an n- or p-dopant has been introduced; and during the processing, introducing a concentration of excess minority carriers into the doped crystalline layer, wherein the doped crystalline layer with the concentration of excess minority carriers has a carrier concentration greater or less than the carrier concentration of a corresponding doped crystalline layer without the concentration of excess minority carriers introduced during processing of the corresponding doped crystalline layer.

In some example implementations of the structure of any preceding or any subsequent example implementation, or any combination thereof, the doped crystalline layer is composed of a semiconductor into which the n- or p-dopant has been introduced, and into which the concentration of excess minority carriers is introduced during processing of the doped crystalline layer.

In some example implementations of the structure of any preceding or any subsequent example implementation, or any combination thereof, the doped crystalline layer is a doped AlₓGa₍₁₋ₓ₎N layer from (0≦x≦1), and the doped crystalline layer with the concentration of excess minority carriers has a carrier concentration between 1×10¹⁴ cm^{-'}and 5×10²⁰ cm⁻³.

In some example implementations of the structure of any preceding or any subsequent example implementation, or any combination thereof, the doped crystalline layer is composed of an insulator into which the n- or p-dopant has been introduced, and into which the concentration of excess minority carriers is introduced during processing of the doped crystalline layer.

In some example implementations of the structure of any preceding or any subsequent example implementation, or any combination thereof, the doped crystalline layer is an oxide, and the doped crystalline layer with the concentration of excess minority carriers has a carrier concentration between 1×10¹⁴ cm⁻³ and 5×10²⁰ cm⁻³.

In some example implementations of the structure of any preceding or any subsequent example implementation, or any combination thereof, processing the doped crystalline layer includes growth of the doped crystalline layer.

In some example implementations of the structure of any preceding or any subsequent example implementation, or any combination thereof, processing the doped crystalline layer includes post-growth processing of the doped crystalline layer.

In some example implementations of the structure of any preceding or any subsequent example implementation, or any combination thereof, the structure is for production of a ultraviolet (UV) light emitting diode.

In some example implementations of the structure of any preceding or any subsequent example implementation, or any combination thereof, the structure is for production of a deep ultraviolet (DUV) laser diode.

In some example implementations of the structure of any preceding or any subsequent example implementation, or any combination thereof, the structure is for production of a power rectifier or a switch.

These and other features, aspects, and advantages of the present disclosure will be apparent from a reading of the following detailed description together with the accompanying drawings, which are briefly described below. The present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as intended, namely to be combinable, unless the context of the disclosure clearly dictates otherwise.

It will therefore be appreciated that this Brief Summary is provided merely for purposes of summarizing some example implementations so as to provide a basic understanding of some aspects of the disclosure. Accordingly, it will be appreciated that the above described example implementations are merely examples and should not be construed to narrow the scope or spirit of the disclosure in any way. Other example implementations, aspects and advantages will become apparent from the following detailed description taken in conjunction with the accompanying drawings which illustrate, by way of example, the principles of some described example implementations.

### BRIEF DESCRIPTION OF THE FIGURES

Having thus described the disclosure in the foregoing general terms, reference will now be made to the accompanying drawings, which are not necessarily drawn to scale, and wherein:

FIG. 1 a metalorganic chemical vapor deposition growth facility implementing above-bandgap illumination as an excitation source, according to an example implementation of the present disclosure;

FIG. 2 schematically illustrates an arrangement of an evaporation chamber with a low energy electron source for reactive evaporation as an excitation source, according to an example implementation of the present disclosure;

FIG. 3 illustrates the calculated ratio of defect concentration with and without UV illumination for point defects with charge state of 0, −1, and −2 in Al_{0.65}Ga_{0.35}N under the assumption that the defect interacts equally with electrons and holes. pₛₛ is the steady state hole concentration, which is directly related to the power density of the above-bandgap illumination, according to an example implementation of the present disclosure; and

FIG. 4 illustrates carrier concentration as a function of SiH₄ flow in Al_{0.65}Ga_{0.35}N films grown with and without above-bandgap UV illumination, where the carrier concentration increase is due to a reduction in compensating point defects, according to an example implementation of the present disclosure.

### DETAILED DESCRIPTION

The present disclosure will now be described more fully hereinafter with reference to example implementations thereof. These example implementations are described so that this disclosure will be thorough and complete, and will fully convey the scope of the disclosure to those skilled in the art. Indeed, the disclosure may be embodied in many different forms and should not be construed as limited to the implementations set forth herein; rather, these implementations are provided so that this disclosure will satisfy applicable legal requirements. As used in the specification and the appended claims, the singular forms “a,” “an,” “the” and the like include plural referents unless the context clearly dictates otherwise. Also, for example, reference may be made herein to quantitative measures, values, relationships or the like (e.g., planar, coplanar, perpendicular). Unless otherwise stated, any one or more if not all of these may be absolute or approximate to account for acceptable variations that may occur, such as those due to engineering tolerances or the like.

During the growth of a doped semiconductor, a defect is intentionally introduced into the host lattice in order to provide free carriers for conduction. As dopant atoms are introduced to the crystal, free carriers are added to the crystal reservoir. As a result, the Fermi level moves from the center of the bandgap toward the band edge corresponding to the majority carriers provided by the dopant atoms. As the Fermi level moves toward the band edge, the formation energy will decrease for charged defects with sign opposite to the dopant (e.g., dopant atoms acting as donors will provide electrons and the Fermi level will move toward the CBM). Compensators tend to decrease the concentration of free majority carriers relative to the concentration of dopant atoms and decrease the mobility as more ionized ion scattering processes are possible. The overall trend is to move the Fermi level close to its intrinsic position. Note that dopant and compensator are defined by their relative abundance, which may be manipulated by growth conditions.

In a compensated system, the dopant species and the compensating species have charge states with opposite signs. The complete compensation reaction can be described by subtracting both ionization reactions for the dopant and compensator plus the condition of charge neutrality, is given by,

2X⁰+2C^{r}+(q−r)h⁺ [symbol] 2X^{q}+2C⁰+(q−r)e⁻ (1)

where X and C stand for respectively the defect and compensating defect, and q and r stand for the corresponding charges of opposite sign. Also in Eq. 1, X⁰ and X^{q} stand for respectively the defect in its neutral state and its ionized state; and C⁰ and C^{r} stand for respectively the compensating defect in its neutral state and its ionized state. The only assumptions made about C^{r} and X^{q} are in regard to their abundance and sign. No assumptions have been made about the nature or location (surface or bulk) of C^{r} and X^{q}, justifying our generalization.

The ratio of ionized compensator to ionized dopant can be used to describe the degree of charge compensation, as R=|r|[C^{r}]/|q|[V^{q}], a strong function of the Fermi level. The smaller this ratio, the less the dopant is compensated and the greater the concentration of (majority) free charge carriers that contribute to conduction. When this ratio is equal to unity, the semiconductor is fully compensated. More interesting is to define the ratio between the degree of charge compensation at equilibrium (R_{eq}) and under a steady-state excitation (R_{SS}) as α, to clearly illustrate any differences brought to compensation by a steady-state excitation. This ratio, when the charged defect interacts equally with electrons and holes, is expressed as:

$$α = \frac{{R}_{SS}}{{R}_{eq}} exp \frac{( q - r ) [ ( {F}_{n} - {E}_{F} ) + ( {F}_{p} - {E}_{F} ) ]}{2 {k}_{B} T} \qquad ( 2 )$$

where E_{F} represents the Fermi energy and Fₙ and Fₚ are the quasi-Fermi energies for electrons and holes under an external steady-state excitation. To facilitate the analysis of this equation, it is important to realize that for an n-type system with a singly charged donor (q−r) is always greater than 0, and for a p-type system with a singly charged acceptor this difference is always lower than 0. Equation (2) becomes the basis for predicting any compensation effects as referenced to an equilibrium state. In the particular case of above bandgap illumination, the following predictions are made:
1. For an n-type wide bandgap system under typical above bandgap illumination conditions, there is no change in the majority carrier concentration, thus Fₙ˜E_{F}. On the other hand, there is a significant change in the minority carrier concentration, thus E_{F}>>Fₚ, making the difference (Fₙ−E_{F})+(Fₚ−E_{F}) less than zero. This makes a less than zero, corresponding to an expected decrease in the degree of compensation.
2. For a p-type wide bandgap system, with a corresponding inversion in signs, and the type of minority and majority carriers, will make the difference (Fₙ−E_{F})+(Fₚ−E_{F}) greater than zero. This also makes a less than zero, corresponding to an expected decrease in the degree of compensation.

It is clear from these predictions that using above-bandgap illumination, there will be a driving force for the reduction of compensating defects (with respect to the equilibrium amount) under any particular process, e.g., during growth or annealing. This is equivalent to injecting excess minority carriers during the process. A simpler way to visualize the basis of this control framework is to consider an “effective move” of the Fermi level to the middle of the bandgap under an external excitation, such as above-bandgap illumination. This renders the semiconductor “effectively intrinsic”, reducing the driving force for the formation of charged compensating defects. This allows for the control of charged point defect formation by modifying the Fermi level of the system through an externally controllable process. This process does not concern itself to the influence of light on the gas phase reactions that may be involved in a chemical vapor deposition process or influence the adatom mobility on the growth surface as the illumination is not sufficient to either: (1) photo dissociate species near the surface, or (2) locally increase the temperature of the substrate. The process only deals with modifying the charge distribution within the growing material.

Excess minority carrier injection to modify the Fermi level (quasi-Fermi energies) can be realized in a variety of ways. Several examples are listed, but this is not an exhaustive list:

1. above bandgap illumination (UV illumination)

2. low energy electron sources

3. surfactant metallic layers

4. electrical injection though existing junctions.

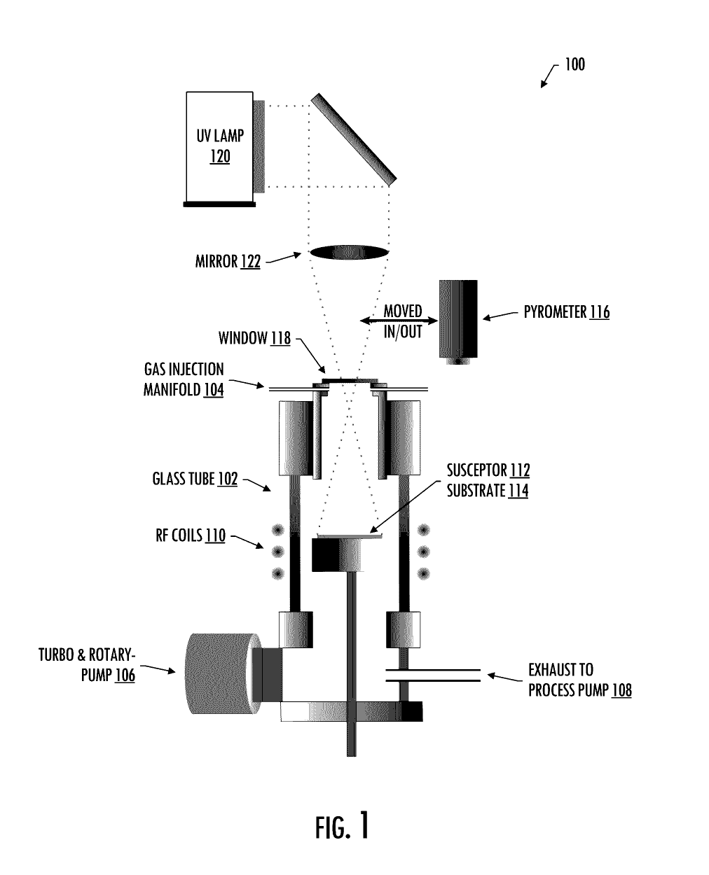

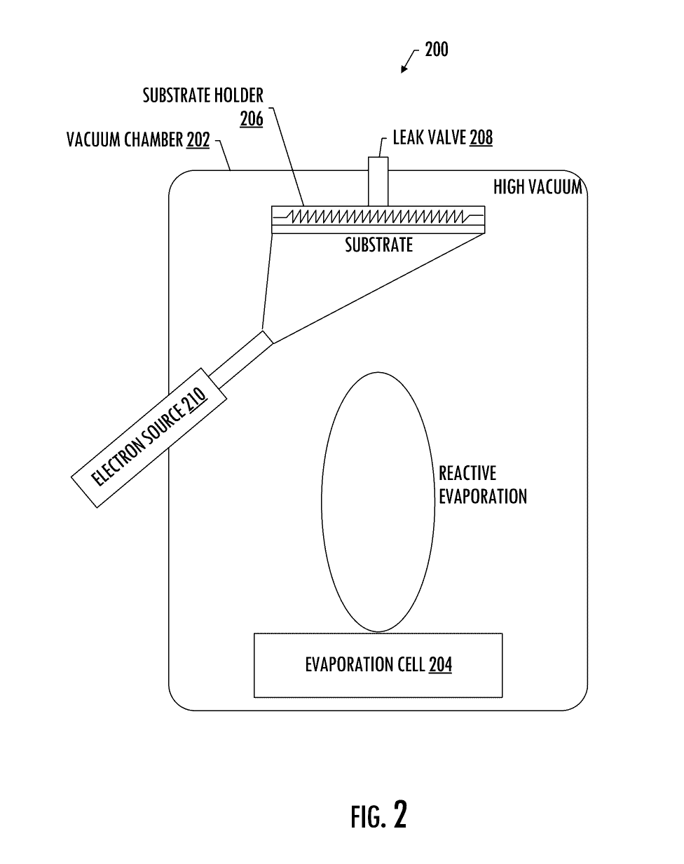

FIGS. 1 and 2 illustrate schematics of example implementations of this scheme based on respectively above bandgap illumination and low energy electron sources. FIG. 1 shows the possible implementation during the growth of III-nitrides semiconductors by metalorganic chemical vapor deposition (MOCVD). In this case, a UV-lamp is used to illuminate the complete substrate during growth of the device structures. Such processes can be used to control the doping scheme of an engineered semiconductor structure.

FIG. 1 more particularly illustrates a system 100 according to some example implementations of the present disclosure. The system includes typical components used for a MOCVD reactor. These typical components are listed within their specific category. The particular example described in FIG. 1 is composed of a glass tube 102 as reactor enclosure, although other reactors have different enclosure as convenient to their heating methods and volumes. As related to the gas injection/transport and pumping, the system also includes gas injection manifold 104 with which gases such as NH₃, H₂, N₂, SiH₄, TMA, TEG, CP₂Mg or the like may be injected. The system includes a turbo and rotary pump system 106 to drive the gas flows, and the corresponding exhaust 108 driven by a process pump.

In addition to the gas management, the system 100 includes substrate handling and heating components such as RF coils 110 and a generator, and a susceptor 112 where substrates 114 may be placed. This configuration is referred to as an inductively-heated reactor. Other configurations exist such as resistively heated or furnace heated. As for conditions monitoring, there may be a moveable pyrometer 116 that measures the temperature through a window 118 on the top of the reactor. Through this window, UV light can be used to illuminate the growing semiconductor material. The illuminations components used in this particular configuration include a UV lamp 120 as a light source, and a mirror 122 for redirection and lens for managing the illumination profile. This particular configuration is an example of possible alternatives through the use of other light sources like LEDs or lasers for illumination.

FIG. 2 shows the possible implementation of a low energy electron source during reactive evaporation of a wide bandgap semiconductor or insulator such as an oxide, as a particular example the p-type oxide NiO:Li. In this case, electrons are used as the minority carriers to inject into the growing p-type film to modify the Fermi level and reduce any compensating defects that would form as a result of the extrinsic doping.

More particularly, FIG. 2 illustrates a system 200 according to another example implementation. This system may be generally described as a reactive evaporation process with a vacuum chamber able to achieve high vacuum conditions along with typical components for the process. These components include a vacuum chamber 202, and an evaporation cell 204 that may include an electron beam system, a Knudsen cell or an evaporation boat. The system may also include a heated substrate holder 206 as used for state-of-the-art deposition of thin films, and as the process is based on reactive evaporation, a leak valve 208 to add a background pressure of any necessary reactive gas that in the case of oxides may be O₂, O₃, or H₂O. And as also shown, the system may include an electron source 210 that may be used to irradiate electrons with sufficient energy to overcome the work function of the material, thus making it an efficient way of injecting minority carrier on the growing film.

As an example of application of this scheme based on above bandgap illumination, consider the case of high Al-content AlGaN alloys, with a wide bandgap and high thermal conductivity, which are attractive for the fabrication of deep ultraviolet (DUV) optoelectronic and high-power electronic devices. In order to realize these devices, it is important that growth of highly conductive n-type AlGaN thin films is achieved. At Al content above 60%, Si-doped AlGaN has been shown to exhibit the same compensation behavior that exists for Mg-doped GaN where the carrier concentration decreases above a critical doping concentration. These reports suggest that compensation is caused by the formation of deep acceptor states, identified as vacancy complexes. More specifically, Slotte et al. showed through positron annihilation spectroscopy (PAS) of Al_{0.63}Ga_{0.37}N films that the W parameter reduces with an increase in Si concentration, indicating an increase in vacancy-related defect centers. These acceptors are incorporated due to the lowering of their formation energies during n-doping, when the Fermi level is close to the conduction band. Compensating point defects also contribute to impurity scattering, thus affecting the carrier mobility. Many studies have been performed on the identification of these defects and their influences on the film properties, but there has been no work on demonstrating a systematic procedure to reduce these compensating point defects and subsequently increase the conductivity of the film. Only procedures either related to the modification of the growth conditions within the system constraints or decreasing the number of extended defects have been explored.

In accordance with some example implementations, a point defect control scheme may use photo-generated minority charge carriers to control the electrochemical potential of the system and increase the formation energies of electrically charged compensating point defects. This results in a lower incorporation of compensating point defects in the film during growth. It has been shown that this Fermi level control scheme reduces the H-passivation in Mg-doped GaN. It has also been shown that the use of above-bandgap illumination during growth of II-VI compounds, such as ZnO, ZnSe, and ZnS, has led to the reduction of compensating defects and a corresponding increase in p-type conductivity, but none of these works have recognized the universality of such a scheme, only considering specific modifications to the growth surface, adatom dynamics, or surface chemical reactions. As indicated above, this Fermi level control process does not involve the influence of light on the gas phase reactions that may be involved in a chemical vapor deposition process nor the adatom mobility on the growth surface, as the illumination intensity typically used in these experiments is not sufficient to either: (1) detectably photo dissociate species near the surface, or (2) locally increase the temperature of the substrate. This non-equilibrium process only deals with modifying the charge distribution within the growing material and the corresponding change of the Fermi level at the surface.

In order to further demonstrate the feasibility and effectiveness of the Fermi level control scheme, Si-doped Al_{0.65}Ga_{0.35}N thin films were grown with and without above-bandgap UV illumination during the growth by MOCVD. The use of above-bandgap UV illumination during growth resulted in Al_{0.65}Ga_{0.35}N films with significantly increased free carrier concentrations and carrier mobility while showing a reduced midgap luminescence. Taken together, these results are strong evidence of a reduction in compensating point defects.

Al_{0.65}Ga_{0.35}N:Si films were grown to a thickness of 600 nm by low-pressure MOCVD on top of an intermediate, nominally undoped AlGaN layer grown on an AlN/sapphire template. Trimethylaluminum (TMA), triethylgallium (TEG), ammonia (NH₃), and diluted silane in nitrogen (SiH₄) were used as sources for Al, Ga, N, and Si, respectively. The Al_{0.65}Ga_{0.35}N:Si films were grown at 1100° C. under a total pressure of 20 Torr with H₂ as a diluent gas. A series of samples was grown over a range of Si doping concentrations with and without exposure to above-bandgap UV illumination. For samples grown with UV illumination, UV light from a nominally 1 kW mercury-xenon arc lamp was directed onto the sample through a UV-transparent window. The configuration of the lamp and reactor are detailed elsewhere.

Samples grown with and without UV illumination were characterized with Hall effect in the Van der Pauw configuration, photoluminescence (PL), high-resolution x-ray diffraction (HRXRD), scanning electron microscopy (SEM), and atomic force microscopy (AFM) measurements. For Hall effect measurements, multiple 1×1 cm² samples were cut from each 2-in wafer. Ti/Al/Ti/Au metal stack was evaporated by e-beam and then annealed by rapid thermal annealing at 900° C. for 60 s to make Ohmic contacts.

Understanding of the basic framework of the Fermi level point defect control scheme is necessary to discuss the experimental results, so, a brief description of the theoretical framework is presented here. The defect concentration ([X^{q}]) in a crystal in thermodynamic equilibrium is directly related to the formation energy (E^{f}) by

$$[ {X}^{q} ] = {N}_{i} {e}^{\frac{- {E}^{f} ( {X}^{q} )}{{k}_{B} T}} , \qquad ( 3 )$$

where q is the charge state of the defect and Nᵢ, considers the number of sites and number of configurations in which the defect may be incorporated. Equation (3) indicates that an increase (decrease) in the formation energy leads to a decrease (increase) in defect concentration. For an equilibrium process, the formation energy of a charged point defect can be expressed as a function of the reference free energy of the crystal (E_{ref}), chemical potential of the specie (μ), and the Fermi energy (E_{F}) with Eq. (4)

E^{f}(X^{q})=E_{ref}(X^{q})−Σᵢnᵢμᵢ+q(E_{F}−E_{V}), (4)

where E_{V} is the energy at the top of the valence band. The reference free energy of the crystal is the difference between the total energy of a bulk crystal with a single point defect and the total energy of a perfect crystal. Equation (4) shows how the Fermi energy directly affects the formation energy of charged defects. More specifically, an increase (decrease) in Fermi energy caused by doping n-type (p-type) results in a decrease in the formation energy of compensating defects regardless of the dopant type.

Under steady-state external excitation and generation of free carriers, the electrochemical potential of a charged point defect may be expressed in terms of the majority and minority carrier quasi-Fermi levels. This extends the analogy between the Fermi level and the electrochemical potential at equilibrium to a steady-state condition where one no longer expects the law of mass action to be satisfied. If the charged defect interacts equally with electrons and holes, the formation energy of a defect during a non-equilibrium steady state process (E_{SS}^{f}) is given by

E_{SS}^{f}(X^{q})=E_{ref}(X_{q})−Σᵢnᵢμᵢ+½[q(Fₙ−E_{V})+q(Fₚ−E_{V})], (5)

where Fₙ and Fₚ represent the quasi-Fermi levels for electrons and holes, respectively.

Steady-state populations of free charge carriers can be generated during growth by introducing an external excitation, such as e-beam irradiation or above-bandgap illumination, the latter being the focus of this work. The 1 kW mercury-xenon arc lamp used in this work generates ˜1.5×10¹⁷ free carriers cm⁻² s⁻¹. This was estimated by dividing the power density of above-bandgap light by ˜4 eV, the approximate bandgap of Al_{0.65}Ga_{0.35}N at 1100° C., and assuming every photon creates an electron-hole pair. This results in a steady state carrier concentration of 10¹²-10¹⁴ cm⁻³ using a minority carrier lifetime of 10⁻¹⁰-10⁻⁹ and absorption coefficient of 10⁵-10⁶ cm⁻¹. Thus, photo-generation will not meaningfully change the majority carrier concentration, however, a significant change in the minority carrier concentration is expected, which will lead to a large shift of the quasi-Fermi level of the minority carriers (holes in the case of Si doping). In general, the wider the bandgap, the larger the shift of the minority quasi-Fermi level for a given minority carrier concentration. Thus, the change in the formation energy due to non-equilibrium steady state conditions can be estimated by subtracting Eq. (5) from Eq. (4)

$$Δ {E}^{f} ( {X}^{q} ) = \frac{- q}{2} ( {F}_{n} - {F}_{p} ) , \qquad ( 6 )$$

Here, it is assumed that the steady state quasi-Fermi level of the majority carriers is practically equal to the equilibrium Fermi level.

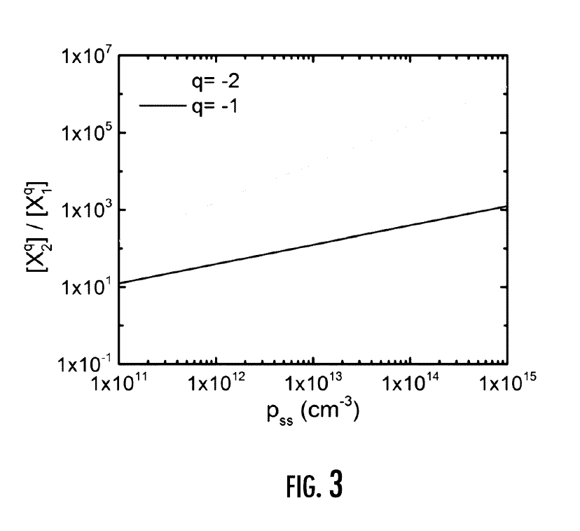

As an illustration of the expected effect, the change in the formation energy for defects with charge states 0, −1, and −2 can be calculated as a function of the steady-state hole concentration, p_{SS}. The quasi-Fermi levels are calculated by using the steady state carrier concentrations and the density of states of the valence and conduction bands. The effective mass for electrons and holes in Al_{0.65}Ga_{0.35}N can be approximated by using Vegard's law and any nonparabolicity of bands can be neglected. The electron and hole concentrations were estimated by using Hall effect measurements and the free carriers generated by the illumination, respectively. Then, using Eq. (3), the change in the formation energy can be directly related to the ratio of the defect concentration with ([X₁^{q}])and without ([X₂^{q}]) UV illumination. This ratio is given in FIG. 3 as a function of steady-state minority carrier concentration.

FIG. 3 shows that relatively low minority carrier concentrations can reduce the concentration of −1 and −2 charged point defects up to six orders of magnitude, which would significantly reduce compensation. As expected, a neutral defect is not affected by the Fermi level. In the case of Si-doped Al_{0.65}Ga_{0.35}N, the main compensators have been preliminarily identified to be negatively charged vacancy complexes either with oxygen or silicon, thus, a change in their incorporation is expected, which would result in an increase in conductivity.

All of the films grown with and without the above-bandgap UV illumination had a very smooth surface with RMS of 800-900 pm in a 5×5 μm² AFM scan. The surfaces contained bilayer step morphology and hillocks caused by the spiral growth mediated by screw dislocations. Film thickness and estimated dislocation densities were also confirmed by cross sectional SEM and HRXRD to be the same for all samples. The total threading dislocation densities ranged from 1 to 1.5×10¹⁰ cm². It is important to note that the composition, surfaces, and thicknesses of the samples grown under UV illumination were identical to the samples grown without UV illumination, indicating no change in growth mode or the enhancement or inhibition of any pre-reactions.

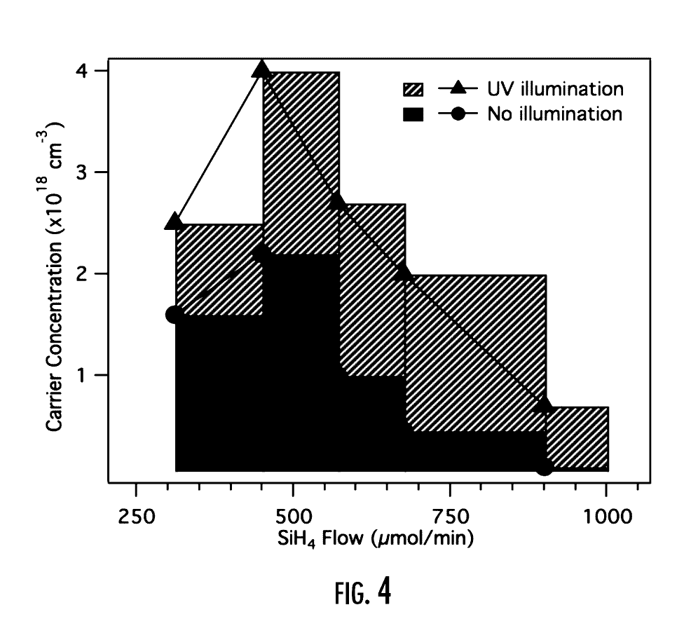

Hall effect measurements were conducted to determine the carrier concentration at different Si doping concentrations and are shown in the below table and FIG. 4.

| | |
|---|---|
| Silane Flow | Carrier Concentration (cm⁻³) |

| (μmol/min) | No Illumination | UV Illumination |
|---|---|---|
| 310 | 1.6 × 10¹⁸ | 2.5 × 10¹⁸ |
| 450 | 2.2 × 10¹⁸ | 4.0 × 10¹⁸ |
| 570 | 1.0 × 10¹⁸ | 2.7 × 10¹⁸ |
| 675 | 4.5 × 10¹⁷ | 2.0 × 10¹⁸ |
| 900 | 1.0 × 10¹⁷ | 7.0 × 10¹⁷ |

For SiH₄ flows from 200 μmol/min to 900 μmol/min, the carrier concentration first increases and then decreases as a function of Si concentration. This behavior has been observed by others. At SiH₄ flows above the critical point of 450 μmol/min, the compensation quickly increases and reduces the free carrier concentration by over an order of magnitude. The mobility steadily decreases as a function of Si concentration due to an increase in ionized impurity scattering. These carrier concentrations and mobilities for the films grown without UV illumination are among the highest reported for this Al content AlGaN films grown on sapphire. Recently, Chichibu et al. reported a maximum carrier concentration of ˜2×10¹⁸ cm⁻² in Al_{0.6}Ga_{0.4}N with threading dislocation density of ˜3×10⁸ cm⁻², which was almost 2 orders of magnitude lower than the dislocation density present in our films. This indicates that point defects play a significant role in compensation in these films.

Corresponding samples grown under above-bandgap UV illumination show an increase in both carrier concentration and mobility indicating a reduction in compensation. More specifically, the carrier concentration increased by up to one order of magnitude and the mobility increased by up to 3 times. Due to the simultaneous increase in the carrier concentration and mobility for samples grown under above bandgap UV illumination, their minimum resistivity decreased from ˜200 mΩcm to ˜60 mΩcm by using UV illumination.

The deep defect luminescence related to vacancy complexes was also reduced in the films grown under UV illumination. These emissions have been observed by others and identified as originating from a conduction band to deep acceptor state transition. A reduction in this luminescence further indicates that the improved conductivity was caused by a reduction of point defects incorporated in the films during growth. The decrease in midgap luminescence was observed in all films grown under UV illumination.

These experimental results indicate a reduction in compensation of 1-2×10¹⁸ cm⁻³ which is less than 10%, at best, of the predicted reduction using FIG. 3. The disagreement between the semi-quantitative model and the observed reduction arises from the assumption that the process is fully efficient at the used illumination conditions and does not consider a system with multiple types of interacting defects or the existence of an illumination intensity threshold necessary for a higher efficiency. Furthermore, it is proposed that the Fermi level may be pinned at the surface, meaning that the generated carriers would have insignificant effect at the surface and have an increased effect away from the surface and deeper in the film (˜2 nm and below), where the Fermi level is no longer pinned.

Example implementations of the present disclosure may therefore provide a Fermi level control scheme during the growth of Al_{0.65}Ga_{0.35} N to control point defect incorporation. This Fermi level control scheme uses above-bandgap UV illumination during growth to create a non-equilibrium steady state population of minority carriers, thereby increasing the formation energy and reducing the incorporation of compensating defects. By reducing compensation, free carrier concentration and mobility were significantly increased, while the midgap luminescence was reduced. More specifically, the carrier concentration and mobility increased up to an order of magnitude and by a factor of 3, respectively. With this knowledge, the proposed point defect control scheme can be implemented to ultimately increase the n- and p-conductivity of any wide bandgap material.

At least some example implementations may lead to AlₓGa₍₁₋ₓ₎N alloys from (0≦x≦1) with controllable carrier concentrations between 1×10¹⁴ cm⁻³ and 5×10²⁰ cm⁻³. Example implementations may also lead to measurable Hall mobility that reach the expected theoretical limit for alloy scattering or their single end members. Example implementations may also be applicable to any of a number of other semiconductors. For example, GaN may also show significant defect modification. It was observed by cathodoluminescence a reduction in the below bandgap luminescence associated with the impurity C in GaN. These results are unique and demonstrate a powerful tool for control of compensating point defects in wide bandgap semiconductors.

The foregoing description of use of the article(s) can be applied to the various example implementations described herein through minor modifications, which can be apparent to the person of skill in the art in light of the further disclosure provided herein. The above description of use, however, is not intended to limit the use of the article but is provided to comply with all necessary requirements of disclosure of the present disclosure. Any of the elements shown in the article(s) illustrated in FIGS. 1 and 2 an or as otherwise described above may be included in an appropriate system according to the present disclosure.

Many modifications and other implementations of the disclosure set forth herein will come to mind to one skilled in the art to which these disclosure pertain having the benefit of the teachings presented in the foregoing descriptions and the associated drawings. Therefore, it is to be understood that the disclosure are not to be limited to the specific implementations disclosed and that modifications and other implementations are intended to be included within the scope of the appended claims. Moreover, although the foregoing descriptions and the associated drawings describe example implementations in the context of certain example combinations of elements and/or functions, it should be appreciated that different combinations of elements and/or functions may be provided by alternative implementations without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A structure comprising:
a doped crystalline layer composed of a semiconductor or an insulator into which an n- or p-dopant has been introduced, and into which a concentration of excess minority carriers has been introduced during processing of the doped crystalline layer,
wherein the doped crystalline layer with the concentration of excess minority carriers has a carrier concentration greater or less than the carrier concentration of a corresponding doped crystalline layer without the concentration of excess minority carriers introduced during processing of the corresponding doped crystalline layer.

2. The structure of claim 1, wherein the doped crystalline layer is composed of a semiconductor into which the n- or p-dopant has been introduced, and into which the concentration of excess minority carriers has been introduced during processing of the doped crystalline layer.

3. The structure of claim 2, wherein the doped crystalline layer is a doped AlₓGa₍₁₋ₓ₎N layer from (0≦x≦1), and the doped crystalline layer with the concentration of excess minority carriers has a carrier concentration between 1×10¹⁴ cm⁻³ and 5×10²⁰ cm⁻³.

4. The structure of claim 1, wherein the doped crystalline layer is composed of an insulator into which the n- or p-dopant has been introduced, and into which the concentration of excess minority carriers has been introduced during processing of the doped crystalline layer.

5. The structure of claim 4, wherein the doped crystalline layer is an oxide, and the doped crystalline layer with the concentration of excess minority carriers has a carrier concentration between 1×10¹⁴ cm³ and 5×10²⁰ cm³.

6. The structure of claim 1, wherein the concentration of excess minority carriers has been introduced during growth of the doped crystalline layer.

7. The structure of claim 1, wherein the concentration of excess minority carriers has been introduced during post-growth processing of the doped crystalline layer.

8. The structure of claim 1 for production of a ultraviolet (UV) light emitting diode.

9. The structure of claim 1 for production of a deep ultraviolet (DUV) laser diode.

10. The structure of claim 1 for production of a power rectifier or a switch.

11. A structure prepared by a process comprising:
processing a doped crystalline layer composed of a semiconductor or an insulator into which an n- or p-dopant has been introduced; and during the processing,
introducing a concentration of excess minority carriers into the doped crystalline layer,
wherein the doped crystalline layer with the concentration of excess minority carriers has a carrier concentration greater or less than the carrier concentration of a corresponding doped crystalline layer without the concentration of excess minority carriers introduced during processing of the corresponding doped crystalline layer.

12. The structure of claim 11, wherein the doped crystalline layer is composed of a semiconductor into which the n- or p-dopant has been introduced, and into which the concentration of excess minority carriers is introduced during processing of the doped crystalline layer.

13. The structure of claim 12, wherein the doped crystalline layer is a doped AlₓGa₍₁₋ₓ₎N layer from (0≦x≦1), and the doped crystalline layer with the concentration of excess minority carriers has a carrier concentration between 1×10¹⁴ cm⁻³ and 5×10²⁰ cm⁻³.

14. The structure of claim 11, wherein the doped crystalline layer is composed of an insulator into which the n- or p-dopant has been introduced, and into which the concentration of excess minority carriers is introduced during processing of the doped crystalline layer.

15. The structure of claim 14, wherein the doped crystalline layer is an oxide, and the doped crystalline layer with the concentration of excess minority carriers has a carrier concentration between 1×10¹⁴ cm⁻³ and 5×10²⁰ cm⁻³.

16. The structure of claim 11, wherein processing the doped crystalline layer includes growth of the doped crystalline layer.

17. The structure of claim 11, wherein processing the doped crystalline layer includes post-growth processing of the doped crystalline layer.

18. The structure of claim 11 for production of a ultraviolet (UV) light emitting diode.

19. The structure of claim 11 for production of a deep ultraviolet (DUV) laser diode.

20. The structure of claim 11 for production of a power rectifier or a switch.
